(19) United States
(12) Patent Application Publication
(10) Pub. No.: US 2019/0323116 A1
(43) Pub. Date: Oct. 24, 2019

(54) Process for Producing a Component having Anti-Corrosion Coating

(71) Applicant: Ekkehardt Linsen, Müstair (CH)

(72) Inventor: Ekkehardt Linsen, Müstair (CH)

(73) Assignee: HOPPE Holding AG, Müstair (CH)

(21) Appl. No.: 16/318,469

(22) PCT Filed: Jun. 21, 2017
(86) PCT No.: PCT/EP2017/065320

§ 371 Date: Jul. 1, 2019

(30) Foreign Application Priority Data
Jul. 14, 2016 (DE) 10 2016 112 928.3

(51) Int. Cl. C23C 14/02; C23C 14/06; C23C 14/32; C23C 28/00; C23C 14/16

(52) U.S. Cl. CPC C23C 14/025; C23C 14/027; C23C 14/0688; C23C 14/165; C23C 28/321; C23C 28/341; C23C 28/343; C23C 14/325

(57) ABSTRACT

The invention relates to a process for producing a component (10) that has a metallic substrate (14), in particular made of brass or aluminum, and an anti-corrosion coating applied to a surface of the substrate (14). The anti-corrosion coating (16) comprises a diffusion layer (20) and an anti-corrosion layer (30). The diffusion layer (20) is applied directly to the surface (18) of the substrate (14), and comprises, at least in sections, a material that generates a space-filling corrosion product (38) when it comes in contact with a corrosion agent (32). The anti-corrosion layer (30) has at least one first anti-corrosion layer (22a, 22b, 22c) and at least one second anti-corrosion layer (24a, 24b). The first anti-corrosion layer (22a, 22b, 22c) forms a barrier for the corrosion agent (32), and the second anti-corrosion layer (24a, 24b) contains a material that generate a space-filling corrosion product (38) when it comes in contact with a corrosion agent (32. The process comprises the following steps:
a. provision of the metallic substrate (14), wherein the surface (18) of the substrate (14) is chemically and physically cleaned,
b. application of a diffusion layer (20) to the substrate (14),
c. application of a first anti-corrosion layer (22a), and
d. application of the second anti-corrosion layer (24a) to the first anti-corrosion layer (22a).
   The diffusion layer (20) ant the first anti-corrosion layer (22a) and second anti-corrosion layer (24a) are applied with a physical vapor deposition process, in particular an arc vaporization process or a cathode sputtering process.

The invention relates to a process for producing a component that has a metallic substrate, in particular made of brass or aluminum, and an anti-corrosion coating on the substrate.

Various processes are known from the prior art for producing an anti-corrosion coating for components made of a metallic substrate, in order to protect the substrate from coming in contact with a corrosion agent, e.g. water or water vapor, and thus from corrosion. With components for windows and doors, e.g. handles or metal fittings, electroplating processes or so-called wet-chemical methods are often used to obtain a uniform coating of the component with an anti-corrosion coating. These processes are very complex, however. There is also a desire to improve the protection against corrosion for these components, in order to improve the durability of these components when they come in contact with corrosion media.

The object of the invention is to create an improved process for producing a component that has an anti-corrosion coating.

The main features of the invention are defined in the characterizing portion of claim 1. Embodiments are the subject matter of claims 2 to 14.

The problem addressed by the invention is solved by a process for producing a component that has a metallic substrate, in particular made of brass or aluminum, and an anti-corrosion coating on a surface of the substrate. The anti-corrosion coating has a diffusion layer and an anti-corrosion layer. The diffusion layer is applied directly to the surface of the substrate, and comprises a material that generates a space-filling corrosion product, at least in areas, when it comes in contact with a corrosion agent. The anti-corrosion layer has at least one first anti-corrosion layer and at least one second anti-corrosion layer. The first anti-corrosion layer forms a barrier for the corrosion agent, and the second anti-corrosion layer contains a material that generates a space-filling corrosion product when it comes in contact with a corrosion agent. The process comprises the following steps:
a. provision of the metallic substrate, wherein the surface of the substrate is chemically and physically cleaned,
b. application of a diffusion layer to the substrate,
c. application of a first anti-corrosion layer, and
d. application of the second anti-corrosion layer to the first anti-corrosion layer.

The diffusion layer, as well as the first anti-corrosion layer and the second anti-corrosion layer are each applied with a physical vapor deposition process, in particular an arc vaporization process or a cathode sputtering process.

The layered structure comprising a diffusion layer applied directly to the substrate, and numerous anti-corrosion layers with different properties, results in an improved protection against corrosion. The first anti-corrosion layer forms a barrier for the corrosion agent, which prevents the corrosion agent from coming in contact with the component or the layer beneath the first anti-corrosion layer. If the first anti-corrosion layer has defects or is damaged, the corrosion agent comes in contact with a second anti-corrosion layer lying beneath it, which encases the corrosion agent, and can seal the defect, such that the corrosion agent is prevent from spreading. If damage extends to the substrate, a contaminating corrosion agent can be encompassed by the diffusion layer, and the defect can be sealed off by the corrosion product, such that the substrate is protected against coming in contact with the corrosion agent, and is therefore protected against corrosion. A further advantage of the layered structure, or the process for the production thereof is that it is possible to produce a coating on the component that does not contain chrome.

With a physical vapor deposition process, it is possible to easily apply the different layers to the substrate, such that it is possible to produce the component efficiently and inexpensively.

A sufficient protection against corrosion for the substrate is achieved by applying a first and second anti-corrosion layer. In order to improve the corrosion protection, numerous first and/or numerous second anti-corrosion layers can also be applied, wherein the first anti-corrosion layer and the second anti-corrosion layer are applied in alternating layers. If an anti-corrosion layer is damaged or has a defect, the underlying layer can prevent a spreading of the corrosion agent toward the substrate. In particular, the second anti-corrosion layers can seal off defects or damages when they comes in contact with the corrosion agent, such that the substrate is reliably protected against corrosion.

The diffusion layer is preferably produced from niobium and/or tantalum, wherein the niobium and/or tantalum is vaporized in a nitrogen atmosphere, and conducted to the substrate.

A negative voltage can be applied to the substrate during the application of the diffusion layer. This is preferably a voltage of numerous hundreds of volts. The vaporized metal ions are accelerated toward the substrate by the voltage, and diffuse into the substrate.

The voltage is reduced over time during the application of the diffusion layer, in particular to only a few volts. As a result, the diffusion of the metal ions in the substrate decreases, and these ions accumulate increasingly on the surface of the substrate. The voltage can be reduced incrementally or continuously, thus having an effect on the formation of the diffusion layer. With a continuous voltage reduction, there is a smooth transition between the diffusion in the substrate and the accumulation on the surface of the substrate.

As a result of the high voltage level at the start of the process, and the subsequent reduction of the voltage, niobium and/or tantalum are increasingly diffused into the substrate, while niobium nitride and/or tantalum nitride increasingly accumulate on the surface of the substrate. The portion of niobium and/or tantalum thus decreases toward the first anti-corrosion layer, and the portion of niobium nitride and/or tantalum nitride increases.

The niobium can react with water, resulting in a space-filling corrosion product, by means of which defects or damages in the diffusion layer can be sealed. Protection against corrosion is also ensured with damage to the component extending as far as the substrate, because the defect, or the damage is quickly sealed by the swelling of the diffusion layer. In this manner, the substrate is reliably prevented from coming in contact with water or some other corrosion agent.

The niobium nitride, or the tantalum nitride in the upper region of the diffusion layer, facing away from the substrate, does not react with water or some other corrosion agent, and thus protects the substrate from corrosion, if the diffusion layer does not exhibit any defects or damage.

The first anti-corrosion layers can be made of niobium and/or tantalum, wherein the niobium and/or tantalum is vaporized in a nitrogen atmosphere, and conducted to the substrate, such that a layer made of niobium nitride and/or tantalum nitride is obtained. The niobium nitride and/or tantalum nitride does not react with water, such that an ideal water barrier, or water vapor barrier, is formed. The first anti-corrosion layers can exhibit the same composition as the diffusion layer at the transition to the first anti-corrosion layer, such that a first anti-corrosion layer, adjacent to the diffusion layer, forms a continuation of the diffusion layer. It is also possible for the portion of nitrogen to be greater than in the diffusion layer. Optionally, the first anti-corrosion layer can contain low quantities of other metals and/or gases, which have no effect on the functioning of the first anti-corrosion layer.

The second anti-corrosion layers can each be produced from a mixture of niobium, zirconium, and/or molybdenum and nitrogen, and/or from a mixture of tantalum, hafnium and/or tungsten and nitrogen, wherein a mixture of niobium and zirconium and/or molybdenum and/or a mixture of tantalum and hafnium and/or tungsten is vaporized in a nitrogen atmosphere, and conducted to the substrate.

As a result, a layer is formed that is composed of niobium nitride doped with zirconium and/or molybdenum, and/or tantalum nitride doped with hafnium and/or tungsten. This doping allows the niobium or tantalum contained therein to react with water because of the low stability of the bond between the niobium and zirconium and/or molybdenum, or between the tantalum and hafnium and/or tungsten. A space-filling corrosion product is obtained through the reaction of the niobium or tantalum with water, by means of which defects or damage in the respective second anti-corrosion layer and/or in an adjacent layer can be sealed. By closing off the defects, a waterproof, or vapor-proof layer is formed, which prevents further contamination by water or water vapor. Optionally, the second anti-corrosion layer can contain low quantities of other metals an/or gases, which have no effect on the functioning of the second anti-corrosion layer.

Optionally, a casing layer and/or a decorative layer can be applied to the anti-corrosion layer, wherein the casing layer and/or decorative layer can be applied with a physical vapor deposition process, in particular an arc vaporization process or a cathode sputtering process.

The casing layer is harder than the substrate. The casing layer can be subjected to high spot loads, and conducts the pressure over a large surface area to the underlying layers. This prevents a spot load to the anti-corrosion layer beneath the casing layer. In particular, spot loads are distributed over a large surface area such that penetration to the substrate is prevented. The surface hardness of the casing layer is preferably multiple times greater than the surface hardness of the substrate, and can be deformed in a plastic manner.

The decorative layer forms a thermal and/or chemical protection for the underlying layers. Moreover, the decorative layer can have an effect on the color of the component.

Because both the casing layer and the decorative layer are applied with the same process as the diffusion layer, or anti-corrosion layer, these layers can be produced easily.

The casing layer can be produced from a mixture of metal and carbon, which is vaporized in a nitrogen atmosphere, and applied to the substrate.

The decorative layer is produced, e.g., from a metal or a metal nitride. Alternatively, other materials can be used that have a high thermal or chemical resistance. In addition to salts and metallic nitrides, covalent nitrides, e.g. titanium nitride, zirconium nitride, silicon nitride can also be used. The color of the decorative layer can be affected by adding other substances. Alternatively, pure metallic surfaces can be used, such as chrome, molybdenum, vanadium, silicon, or titanium.

In a preferred embodiment, at least one layer is diffused into at least a portion of the underlying and/or adjacent layer during the application, such that the layers transition into one another. In particular, the layers can transition into one another incrementally or continuously. The transition between the layers improves the adhesion between the individual layers.

The substrate can be heated before applying the diffusion layer, wherein the temperature is increased during the application of the anti-corrosion layers, the casing layer, and/or the decorative layer.

The surface of the substrate is prepared, for example, before applying the diffusion layer, in particular through a chemical or mechanical cleaning and/or by subjecting it to an inert gas ion beam.

The application of the diffusion layer, the first and second anti-corrosion layers, the casing layer and the decorative layer preferably takes place at a low pressure, in particular a vacuum.

The thicknesses of the individual layers can range from a few nanometers to some micrometers. The thickness of the decorative layer can preferably be up to 250 nanometers.

Further features, details, and advantages of the invention can be derived from the wording of the claims as well as the following description of exemplary embodiments in reference to the drawings. Therein:

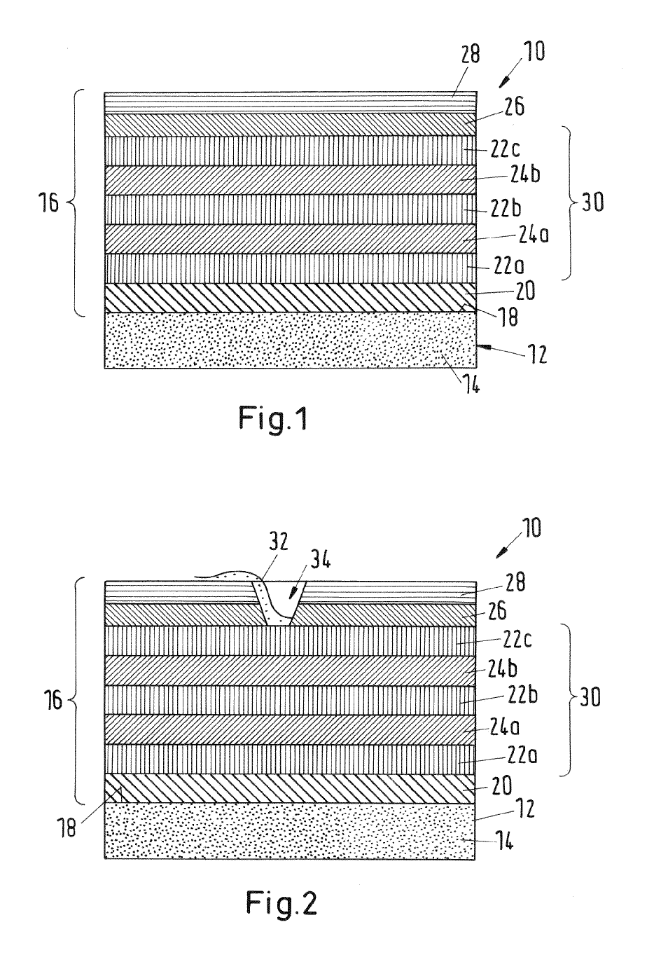

FIG. 1 shows a section of the component according to the invention,

FIG. 2 shows the section of the component in FIG. 1 with a defect in the decorative layer as well as the casing layer,

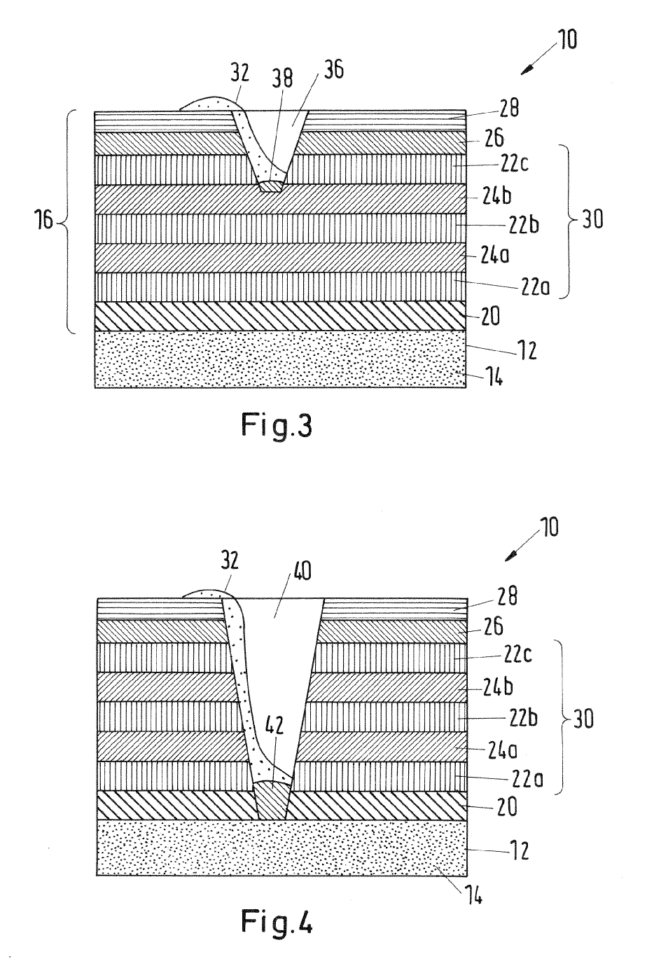

FIG. 3 shows the section of the component in FIG. 1 with a defect in a first anti-corrosion layer,

FIG. 4 shows the section of the component in FIG. 1 with a defect that extends to the substrate, and

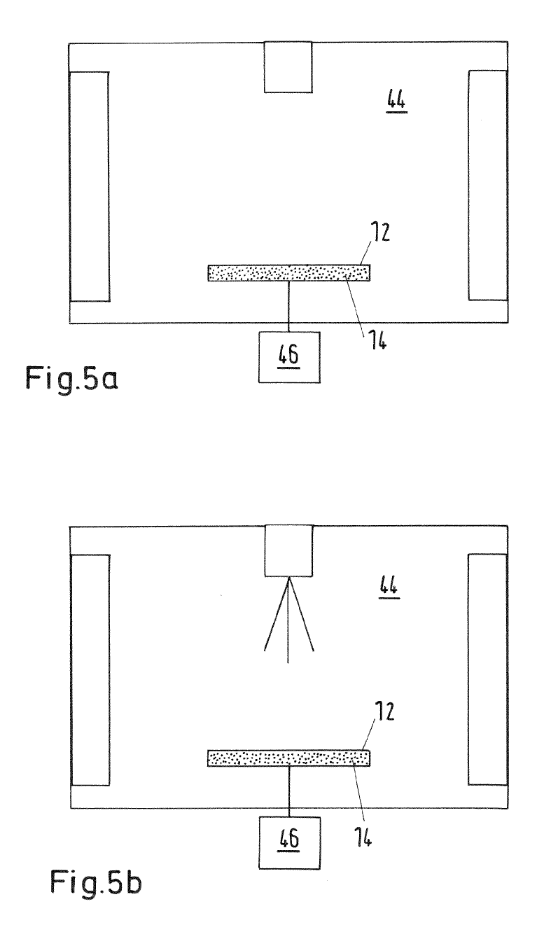

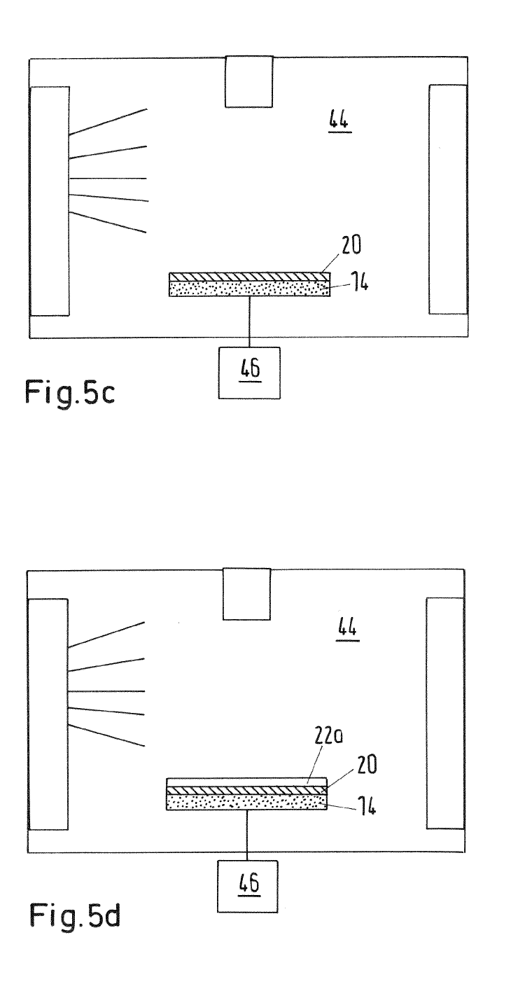

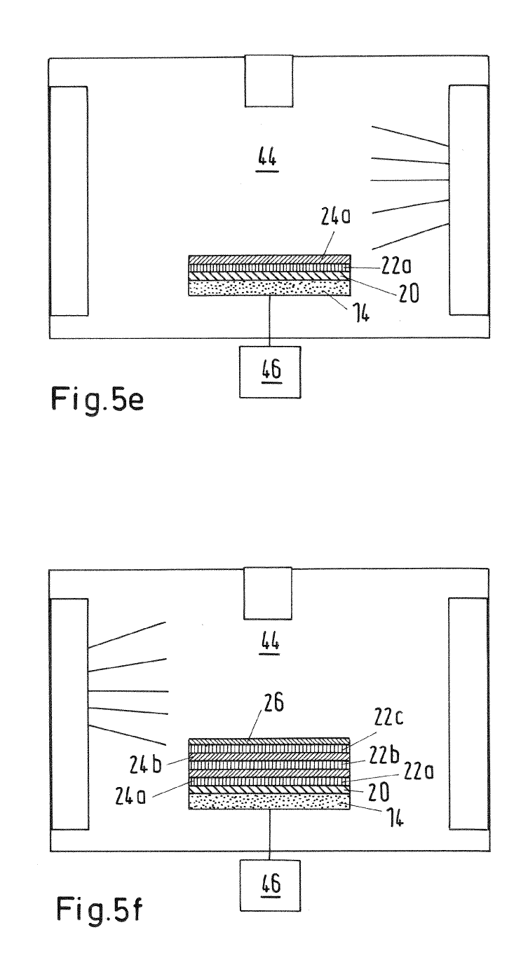

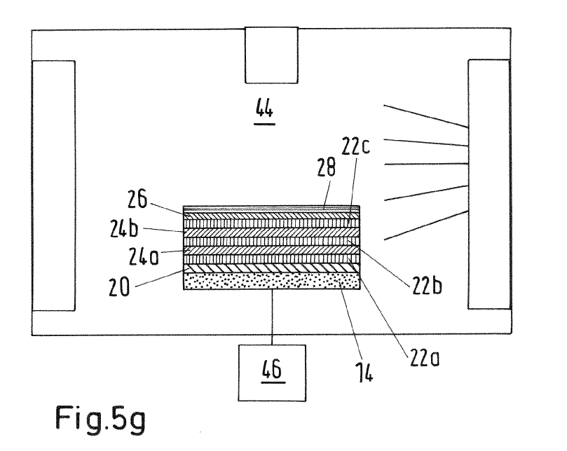

FIGS. 5a to 5g show the steps for the production process for producing the component shown in FIG. 1.

A section of a component is shown in FIG. 1, e.g. a metal fixture or an actuation handle, such as a handle for a window or a door. The component 10 has a core 12 comprised of a substrate 14 and an anti-corrosion coating 16 applied to the surface 18 of the substrate 14.

The anti-corrosion coating comprises a diffusion layer 20, numerous first anti-corrosion layers 22a, 22b, 22c, numerous second anti-corrosion layers 24a, 24b, a casing layer 26 and a decorative layer 28.

The diffusion layer is applied directly to the substrate 14, or diffused in part into the substrate. The diffusion layer 20 contains a material, at least in part, in a region adjacent to the substrate, or diffused therein, that exhibits volume increasing properties when it comes in contact with a corrosion agent, e.g. water or water vapor, e.g., in that the material or a component of the material reacts with the corrosion agent and forms a space-filling corrosion product. In a region of the diffusion layer 20 facing away from the substrate, the diffusion layer 20 contains, at least in part, a material that does not react with water, or a material that has water or water vapor barrier properties. The portion of the material that reacts with water can decrease incrementally or continuously in the direction going away from the substrate, or the portion of materials that do not react with water can incrementally or continuously increase. The material that reacts with water can contain, e.g., niobium, tantalum, or a mixture thereof, or it can be composed entirely of these substances. The water barrier material can contain niobium nitride and/or tantalum nitride, or be composed entirely thereof.

The anti-corrosion layers 22a, 22b, 22c each have a water barrier and/or water vapor barrier function. The first anti-corrosion layers 22a, 22b, 22c each contain a mixture of niobium, tantalum, or a mixture of these substances, and nitrogen, or are formed entirely therefrom. The material forms a columnar structure, which nearly entirely prevents the passage of water or water vapor through it. The first anti-corrosion layers 22a, 22b, 22c are each diffused into the underlying layers 20, 24a, 24b.

The composition of the first anti-corrosion layers 22a, 22b, 22c can correspond to the composition of the diffusion layer 20 in the region of the diffusion layer 20 facing away from the substrate, thus the region adjacent to the first anti-corrosion layer 22a. In such an embodiment, the diffusion layer 20 transitions into the first anti-corrosion layer 22a. Alternatively, the composition of the first anti-corrosion layers 22a, 22b, 22c can also differ from the composition of the diffusion layer 20. By way of example, the first anti-corrosion layers 22a, 22b, 22c exhibit a higher portion of nitrogen. The compositions of the various first anti-corrosion layers 22a, 22b, 22c can likewise vary.

The second anti-corrosion layers 24a, 24b contain a material that has volume-increasing properties when it comes in contact with a corrosion agent. The second anti-corrosion layers 24a, 24b contain, e.g., a niobium nitride doped with zirconium and/or molybdenum, and/or a tantalum nitride doped with hafnium and/or tungsten, or are entirely composed thereof. The material of the second anti-corrosion layers 24a, 24b forms an amorphous structure with defects, which is capable of absorbing and storing a corrosion agent. The bonds between zirconium or molybdenum and niobium nitride, or between hafnium or tungsten and tantalum nitride are very weak. Water entering these layers can thus react with the niobium or tantalum contained in the respective second anti-corrosion layers 24a, 24b. A space-filling corrosion product is obtained with this reaction, by means of which the corrosion agent can be bonded, and the defects can be closed off.

The casing layer 26 protects the underlying anti-corrosion layers 22a, 22b, 22c, 24a, 24b and the substrate 16 from mechanical loads, e.g. friction. The casing layer 26 contains a metal nitride displaced with carbon, or is composed entirely thereof. Alternatively, the casing layer 26 can be composed of a pure metal or metal carbide, or an arbitrary combination of metal, nitride and carbon. So-called DLC layers (diamond-like carbon layers) are also a possibility. A zirconium carbon nitride is used for the production process. In any case, the casing layer is many times harder than the substrate 16. In particular, the casing layer 26 can be subjected to high spot loads, i.e. the casing layer can withstand spot pressures, and conduct the pressure over a large surface area to the underlying first anti-corrosion layer 22c, wherein the casing layer can be deformed in a plastic manner.

The optical appearance of the component 10 is determined by the material of the decorative layer 28. Moreover, the decorative layer 28 can also provide protection against heat or chemicals. By way of example, the decorative layer contains a metal nitride, thus a compound of nitrogen and at least one metal, or is composed entirely thereof. These compounds remain stable over a wide thermal range, and are also resistant to chemicals. Alternatively, salt-type nitrides, or covalent nitrides such as titanium nitride, zirconium nitride or silicon nitride, can also be used. It is possible to affect the color of the decorative layer by adding further substances. By way of example, colors such as anthracite, black, or brown can be obtained by adding carbon. Alternatively, pure metal surfaces such as chrome, molybdenum, vanadium, silicon, or titanium can also be used.

The first and second anti-corrosion layers 22a, 22b, 22c, 24a, 24b collectively form an anti-corrosion layer 30, which protects the substrate, together with the diffusion layer 20, against contact with a corrosion agent 32 (see FIG. 2), in particular water or water vapor, and thus against corrosion.

There are three first anti-corrosion layers 22a, 22b, 22c and two second anti-corrosion layers 24a, 24b in the embodiment shown herein. The number of first anti-corrosion layers 22a, 22b, 22c and the second anti-corrosion layers 24a, 24b can be selected arbitrarily, depending on the desired quality of the corrosion protection.

If a corrosion agent 32, e.g. water, passes through a defect in the decorative layer 28 and the casing layer 26, the corrosion agent 32 comes in contact with the underlying first anti-corrosion layer 22c (see FIG. 2). The first anti-corrosion layer 22c has water barrier properties as a result of the columnar structure of the first anti-corrosion layer 22c, such that the corrosion agent 32 is unable to enter the underlying second anti-corrosion layer 24b.

The corrosion agent 32 can only pass through the first anti-corrosion layer 22c and come in contact with the underlying second anti-corrosion layer 24b when there are defects 32 or damage in the first anti-corrosion layer 22c (see FIG. 3). Such a defect 36 can result from a defect in the columnar structure or mechanical damage. If there is such a defect 36, the corrosion agent 32 reacts with the niobium and/tantalum in the second anti-corrosion layer 24b, resulting in a space-filling corrosion product 38. As a result of this increase in volume, the defect 38 in the second anti-corrosion layer 22c is sealed, preventing further penetration by the corrosion agent 32. When all of the defects 40 in the second anti-corrosion layer 24b are sealed off, the second anti-corrosion layer 24b likewise cannot be penetrated by the corrosion agent.

The corrosion product 38 is formed in the second anti-corrosion layer 24b and bonds the corrosion medium 32. The corrosion medium 32 cannot enter the underlying layers 22b, 24a, 22a, 20, thus preventing a spreading of the corrosion agent 32. The corrosion product 38 remains in the second anti-corrosion layer 24b, such that there are no adverse effects to the visual appearance of the component 10 caused by the corrosion product 38.

The repeated alternation between the first anti-corrosion layers 22a, 22b, 22c and second anti-corrosion layers 24a, 24b improves the quality of the corrosion protection. If, for example, the defect 36 in the first anti-corrosion layer 22c cannot be sealed off by the underlying second anti-corrosion layer 24b, or if this layer likewise has a defect, further penetration of the corrosion agent 32 is prevented by the corrosion layer 22b. In a manner analogous to that of the second anticorrosion layer 24b, the second anti-corrosion layer 24a can also seal off defects in the first anti-corrosion layer 22b.

If a defect, e.g. a mechanical damage, extends to the substrate 14, the diffusion layer 20 forms an additional protection against corrosion. The niobium or tantalum in the diffusion layer can likewise react with the corrosion agent 32, forming a space-filling corrosion product 42, by means of which the defect 40 can be sealed off (FIG. 4).

Because the diffusion layer 20 is diffused at least in part into the substrate 14, the corrosion agent 32 is also unable to come between the diffusion layer 20 or the anti-corrosion coating 16 and the substrate. The corrosion agent 32 is unable to spread out underneath these anti-corrosion layers 22a, 24a, 22b, 24b, 22c, and the adhesion between the layers 20, 22a, 24a, 22b, 24b, 22c is improved.

The diffusion layer 20, the first anti-corrosion layers 22a, 22b, 22c, the second anti-corrosion layer 24a, 24b, the casing layer 26, and the decorative layer 28 are each applied to the substrate 14 or component 10 with a physical vapor deposition process, in particular an arc vaporization process or a cathode sputtering process. In these processes, the coating material is vaporized in a physical process, and subsequently used to coat the substrate. The coating material condenses on the substrate, and forms a layer.

The process for producing the component 10 shall be described below in reference to FIGS. 5a to 5g.

The substrate is provided in a first process step (FIG. 5a), placed in a processing chamber 44, and cleaned, both chemically and physically, thus removing any grease, oil, or other contaminants. The surface 18 of the substrate 16 is subsequently exposed to an inert gas ion beam, e.g. argon, and hydrogen, in a vacuum, by means of which carbon compounds and oxygen are reduced on the surface 18 of the substrate 14 (FIG. 5b). After this step, the surface 18 is metallically pure, and activated for bonding with metal ions or metal atoms.

The diffusion layer 20 is subsequently applied (FIG. 5c). For this, a pure nitrogen atmosphere is generated in the processing chamber 44 with low pressure, in which niobium and/or tantalum vaporizes, and is subsequently deposited on the substrate 14. The niobium and/or tantalum is in its solid state, and is vaporized, for example, with an electric arc. The ratio of niobium to tantalum can be varied arbitrarily.

The substrate 14 is heated to ca. 120° C. prior to applying the diffusion layer, e.g. through infrared radiation. Moreover, a negative voltage of numerous hundred volts is applied to the substrate 14 by a voltage source 46. As a result of the voltage applied thereto, the vaporized metal ions are accelerated toward the substrate 14, and diffused into the substrate 14. In the further course of the process, the voltage is reduced, such that the diffusion of the metal ions into the substrate decreases, and these ions are increasingly deposited onto the surface of the substrate 14. The voltage can be reduced incrementally or continuously, thus having an effect on the formation of the diffusion layer 20. With a continuous reduction in voltage, there is a smooth transition from the diffusion in the substrate 14 to the accumulation on the surface of the substrate 14. The metal ions continue to accelerate toward the substrate 14 with the low residual voltage.

The process is continued until the desired layer thickness of the diffusion layer 20 is obtained.

Niobium and/or tantalum is increasingly diffused into the substrate 14 while niobium nitride and/or tantalum nitride increasingly accumulates on the surface of the substrate through this process. A diffusion layer 20 is obtained, which contains a large quantity of niobium and tantalum in a lower region diffused into the substrate 14 or adjacent to the substrate, and contains a large quantity of niobium nitride and tantalum nitride in an upper region, away from the substrate. The portion of niobium and/or tantalum decreases away the substrate 14, or toward the first anti-corrosion layer 22a, and the portion of niobium nitride and/or tantalum nitride increases.

The first anti-corrosion layer 22a is subsequently applied in that niobium and/or tantalum are vaporized in the pure nitrogen atmosphere by the electric arc, resulting in an accumulation of niobium nitride and tantalum nitride on the substrate 14, or on the diffusion layer 20 (FIG. 5d). The composition of the first anti-corrosion layer 22a can substantially conform to the composition of the diffusion layer 20 in the region adjacent to the first anti-corrosion layer. It is also possible, however, for these compositions to differ.

In order to improve the bond between the diffusion layer 20 and the first anti-corrosion layer, the transition between the production of the diffusion layer 20 and the first anti-corrosion layer 22a can be smooth, i.e. the production of the diffusion layer 20 is continuously or incrementally reduced, while the production of the first anti-corrosion layer 22a is continuously or incrementally increased. As a result, the first corrosion layer 22a can diffuse into the diffusion layer 20.

The process is continued until the desired layer thickness of the first anti-corrosion layer 22a is obtained.

The second anti-corrosion layer 24 is subsequently applied in that niobium is vaporized with zirconium and/or molybdenum, and/or tantalum is vaporized with hafnium and/or tungsten (FIG. 5e). The ratio of niobium compounds to tantalum compounds can likewise be adjusted arbitrarily, as with the ratio of zirconium to tungsten, or the ration of hafnium to tungsten.

In a manner analogous to the production of the diffusion layer 20 and the first anti-corrosion layer 22a, the transition between the production of the first anti-corrosion layer 22a and the second anti-corrosion layer 24a can be smooth, such that these layers transition into one another incrementally or continuously, or the second anti-corrosion layer 24a diffuses into the first anti-corrosion layer 22a.

The first anti-corrosion layers 22b, 22c and the second anti-corrosion layer 24b are applied in a manner analogous to the first anti-corrosion layer or the second anti-corrosion layer 24a, wherein the layers 22b, 24b, 22c likewise transition into one another.

The pressure during the production of the diffusion layer 20, the first anti-corrosion layers 22a, 22b, 22c and the second anti-corrosion layers 24a, 24b preferably ranges between less than one tenth of a Pascal and numerous Pascals.

The layer thicknesses of the diffusion layer 20, the first anti-corrosion layers 22a, 22b, 22c, and the second anti-corrosion layers 24a, 24b are normally between a few nanometers and a few micrometers.

It should be noted that there are small amounts of other metals in the diffusion layer 20, the first anti-corrosion layers 22a, 22b, 22c, or the second anti-corrosion layers 24a, 24b, which do not, or only slightly, alter the fundamental properties thereof.

After applying the first anti-corrosion layer 22c, the casing layer 26 is applied in that the material of the casing layer 26 is vaporized in a nitrogen or acetylene atmosphere, and deposited on the component 10 (FIG. 5f). The transition from the production of the final first anti-corrosion layer 22c to the production of the casing layer can also be smooth or incremental, such that the first anti-corrosion layer 22c and the casing layer 26 transition into one another.

The decorative layer 28 is subsequently applied to the casing layer 26, wherein the material of the decorative layer 28 is likewise vaporized with an electric arc, and deposited onto the surface of the component 10 (FIG. 5g). The atmosphere in which the material is vaporized can be adjusted to the composition of the decorative layer 28. Metals such as chrome, molybdenum, vanadium, silicon, titanium, or zirconium, or semimetals are vaporized, for example, in an inert gas atmosphere, in the exclusion of nitrogen, in order to prevent a reaction of the metals or semimetals with the components of the atmosphere. The thickness of the decorative layer 28 is preferably no more than 250 nm.

The temperature of the substrate 14 is continuously increased during the coating process, wherein a temperature of ca. 340° C. is reached after completion of the coating process. The heating of the substrate 14 can be obtained, for example, with infrared radiation. After completion of the coating process, the temperature of the substrate 14, or the component 10, can be reduced, continuously or incrementally. By way of example, the processing chamber 44 is flooded with nitrogen until reaching a pressure of 800 mbar, and allowed to cool to 200° C. after completing the coating process. The nitrogen is subsequently removed, and the processing chamber 44 is flooded with ambient air.

The diffusion layer, the first anti-corrosion layers 22a, 22b, 22c, and the second anti-corrosion layers 24a, 24b, the casing layer 26, and the decorative layer transition into one another in the embodiment described herein, thus improving the adhesion between the layers 20, 22a, 22b, 22c, 24a, 24b, 26, 28. Independently thereof, it is also possible for individual layers 20, 22a, 22b, 22c, 24a, 24b, 26, 28 to be distinct from one another, or the for transitions between the layers 20, 22a, 22b, 22c, 24a, 24b, 26, 28 to differ from one another.

Embodiments without a casing layer 26 and/or without a decorative layer 28 are also conceivable, if there is no need or desire to protect the anti-corrosion layers 22a, 22b, 22c, 24a, 24b, or to give the component a specific visual appearance.

The invention is not limited to the embodiments described above, and instead can be used for numerous applications.

All of the features and advantages that can be derived from the claims, the description, and the drawings, including structural details, spatial configurations, and process steps, may be regarded as substantial to the invention, in and of themselves or in various combinations thereof.

### LIST OF REFERENCE SYMBOLS

10 component

12 core

14 substrate

16 anti-corrosion coating

18 surface of the substrate

20 diffusion layer

22a, 22b, 22c first anti-corrosion layers

24a, 24b second anti-corrosion layers

26 casing layer

28 decorative layer

30 anti-corrosion layer

32 corrosion agent

34 defect in the decorative layer or casing layer

36 defect in the first anti-corrosion layer

38 corrosion product

40 defect in the second anti-corrosion layer

42 corrosion product

44 processing chamber

46 voltage source

1. A process for producing a component (10) that has a metallic substrate (14), in particular comprised of brass or aluminum, and has an anti-corrosion coating (16) on a surface of the substrate (10), characterized in that the anti-corrosion coating (16) comprises a diffusion layer (20) and an anti-corrosion layer (30), wherein the diffusion layer (20) is applied directly to the surface (18) of the substrate (14), and comprises at least one material, at least in sections, which generates a space-filling corrosion product (38) when it comes in contact with a corrosion agent (32), wherein the anti-corrosion layer (30) comprises at least one first anti-corrosion layer (22a, 22b, 22c) and at least one second anti-corrosion layer (24a, 24b), wherein the first anti-corrosion layer (22a, 22b, 22c) forms a barrier for the corrosion agent (32), and the second anti-corrosion layer (24a, 24b) contains a material that generates a space-filling corrosion product (38) when it comes in contact with a corrosion agent (32), comprising the following steps:
a. provision of the metallic substrate (14), wherein the surface (18) of the substrate (14) is chemically and physically cleaned,
b. application of a diffusion layer (20) to the substrate (14),
c. application of a first anti-corrosion layer (22a), and
d. application of the second anti-corrosion layer (24a) to the first anti-corrosion layer (22a),
wherein the diffusion layer (20) and the first anti-corrosion layer (22a) and second anti-corrosion layer (24a) are applied with a physical vapor deposition process, in particular an arc vaporization process or a cathode sputtering process.

2. The process according to claim 1, characterized in that numerous first anti-corrosion layers (22a, 22b, 22c) and/or numerous second anti-corrosion layers (24a, 24b) are applied, wherein the first anti-corrosion layers (22a, 22b, 22c) and the second anti-corrosion layers (24a, 24b) are applied in alternating layers.

3. The process according to claim 1, characterized in that the diffusion layer (20) is made of niobium and/or tantalum, wherein the niobium and/or tantalum is vaporized in a nitrogen atmosphere and conducted to the substrate.

4. The process according to claim 3, characterized in that a negative voltage is applied to the substrate (14) during the application of the diffusion layer (20).

5. The process according to claim 4, characterized in that the voltage is reduced over time during the application of the diffusion layer (20).

6. The process according to claim 1, characterized in that the first anti-corrosion layers (22a, 22b, 22c) are made of niobium and/or tantalum, wherein the niobium and/or tantalum are vaporized in a nitrogen atmosphere, and conducted to the substrate.

7. The process according to claim 1, characterized in that the second anti-corrosion layers (24a, 24b) are produced from a mixture of niobium, zirconium, and/or molybdenum and nitrogen, and/or a mixture of tantalum, hafnium and/or tungsten, and nitrogen, wherein a mixture of niobium and zirconium, and/or molybdenum and/or a mixture of tantalum and hafnium and/or tungsten is vaporized in a nitrogen atmosphere, and conducted to the substrate (14).

8. The process according to claim 1, characterized in that a casing layer (26) and/or a decorative layer (28) are applied to the anti-corrosion layer (30), wherein the casing layer (26) and/or the decorative layer (28) are applied with a physical vapor deposition process, in particular an arc vaporization process or a cathode sputtering process.

9. The process according to claim 8, characterized in that the casing layer (26) is produced from a mixture of metal and carbon, which is vaporized in a nitrogen or acetylene atmosphere, and applied to the substrate.

10. The process according to claim 8, characterized in that the decorative layer (28) is produced from a metal or metal nitride.

11. The process according to claim 1, characterized in that at least one layer (22a, 24a, 22b, 24b, 22c, 26, 28) is at least partially diffused into the underlying and/or adjacent layer (14, 22a, 24a, 22b, 24b, 22c, 26) during the application thereof.

12. The process according claim 1, characterized in that the substrate (14) is heated before applying the diffusion layer (20), wherein the temperature during the application of the anti-corrosion layers (22a, 22b, 22c, 24a, 24b), the casing layer (26), and/or the decorative layer (28), is increased during the application.

13. The process according to claim 1, characterized in that the surface (18) of the substrate (14) is prepared prior to applying the diffusion layer (20), in particular by a chemical or mechanical cleaning, and/or by exposing it to an inert gas ion beam.

14. The process according to claim 1, characterized in that the application of the diffusion layer (20), the first and second anti-corrosion layers (22a, 22b, 22c, 24a, 24b), the casing layer (26) and the decorative layer (28) takes place at low pressure, in particular in a vacuum.
